(19) United States
(12) Patent Application Publication
(10) Pub. No.: US 2011/0224930 A1
(43) Pub. Date: Sep. 15, 2011

(54) SYSTEM AND METHOD FOR DETECTION OF INSECT INFESTATION

(75) Inventors: Alan Walker, Lincoln, NE (US); Kyle Stickelman, Lincoln, NE (US)

(73) Assignee: TOTAL MANUFACTURING CO., Lincoln, NE (US)

(21) Appl. No.: 12/720,773

(22) Filed: Mar. 10, 2010

(51) Int. Cl. G01R 15/00; G01R 27/08

(52) U.S. Cl. 702/65; 324/691; 324/692

(57) ABSTRACT

A system for detecting the presence of an insect/insect larvae may include, but is not limited to: a first electrically conductive crush roller; a second electrically conductive crush roller; a drive motor operably coupled to at least one of the first electrically conductive crush roller and the second electrically conductive crush roller via an electrically isolating coupling; and detection circuitry configured to detect a signal transmitted from the first electrically conductive crush roller to the second electrically conductive crush roller when a conductive material is disposed between the first electrically conductive crush roller to the second electrically conductive crush roller.

### BACKGROUND

Insect infestation is an important quality factor of stored grain and represents a serious and continuing problem for the grain and milling industries. Acceptance of a specific grain lot by millers depends mainly on the numbers of live insects and insect-damaged kernels (IDK) detected before the grain is unloaded from a railcar. The most commonly used method for determining insect contamination and damage is sampling a quantity of grain and sieving insects from the sample, and visual inspection of a portion of the sample for insect-damaged kernels.

However, grain kernels infested by insects may show no indication on their exterior, but often contain hidden larvae. Although grain is inspected for insect infestations upon shipping and receiving, many infested samples may go undetected.

As such, it may be desirable to provide methods and systems for automated detection of both live insects and insect larvae within a grain sample.

### SUMMARY

A system for detecting the presence of an insect/insect larvae may include, but is not limited to: a first electrically conductive crush roller; a second electrically conductive crush roller; a drive motor operably coupled to at least one of the first electrically conductive crush roller and the second electrically conductive crush roller via an electrically isolating coupling; and detection circuitry configured to detect a signal transmitted from the first electrically conductive crush roller to the second electrically conductive crush roller when a conductive material is disposed between the first electrically conductive crush roller to the second electrically conductive crush roller.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 shows a high-level block diagram of a system for detecting the presence of insects/insect larvae within a grain sample;

FIG. 2 shows a front view of an insect infestation detection system;

FIG. 3 shows a perspective view of an insect infestation detection system;

FIG. 4 shows a perspective view of an insect infestation detection system;

FIG. 5 shows an exploded view of portions of an insect infestation detection system;

FIG. 6 shows a cross-sectional view of portions of an insect infestation detection system;

FIG. 7 shows a graphical representation of insect infestation detection system data;

FIG. 8 shows a high-level logic flowchart of a process.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

An insect infestation detection system 10 may be operable to receive a quantity of grain that may contain one or more insects and/or insect larvae. The system 10 may detect the presence of such insects and/or insect larvae through comparisons between a baseline conductivity of the subject grain sample and an elevated conductivity resulting from the presence of any insects and/or insect larvae.

The system 10 may be employed in numerous environments. For example, the system may be used in simple analytical context where a sample of grain is to be tested for insect/insect larvae infestation. In another example, the system may be incorporated as part of a larger milling system where the circuitry described below may be operably coupled to one or more sets of modified crush/shear rollers in order to provide real-time quality control information concerning the grain feed stock (e.g. moisture level and contamination) and/or infestation levels. Such information may be used to direct output stream allocation or monitor operating conditions.

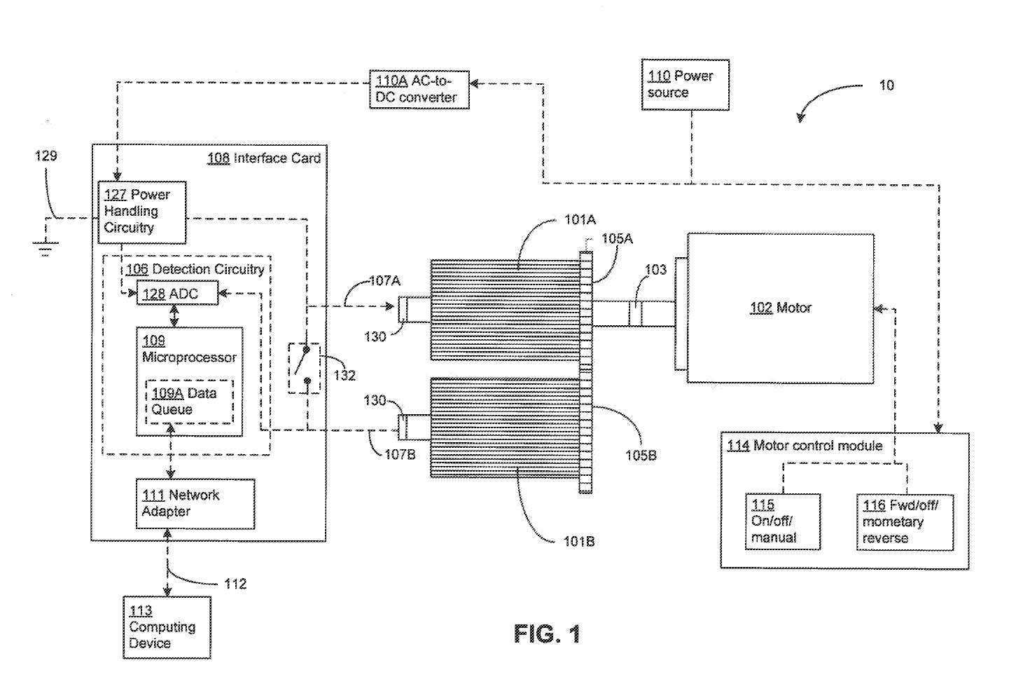

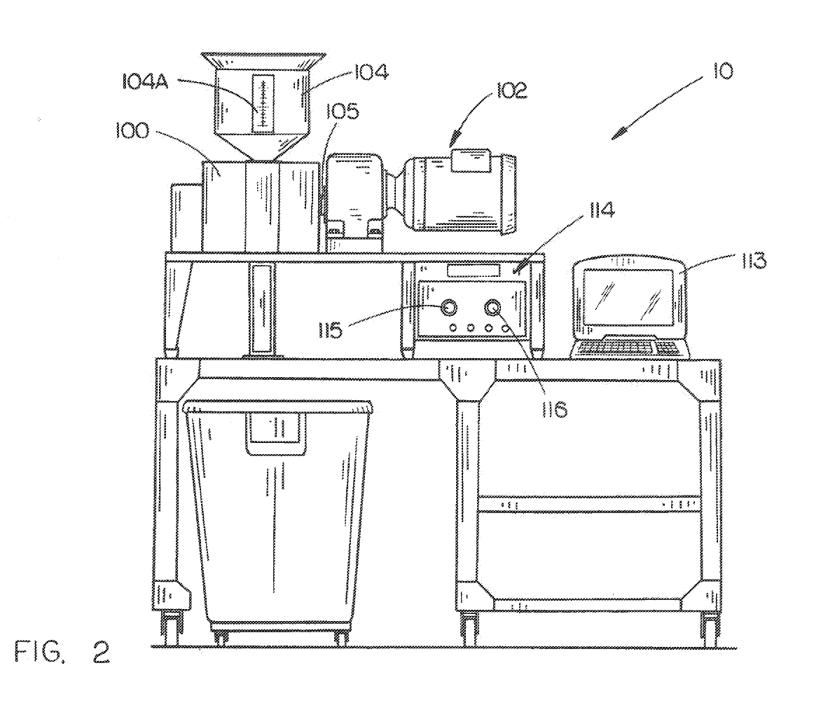

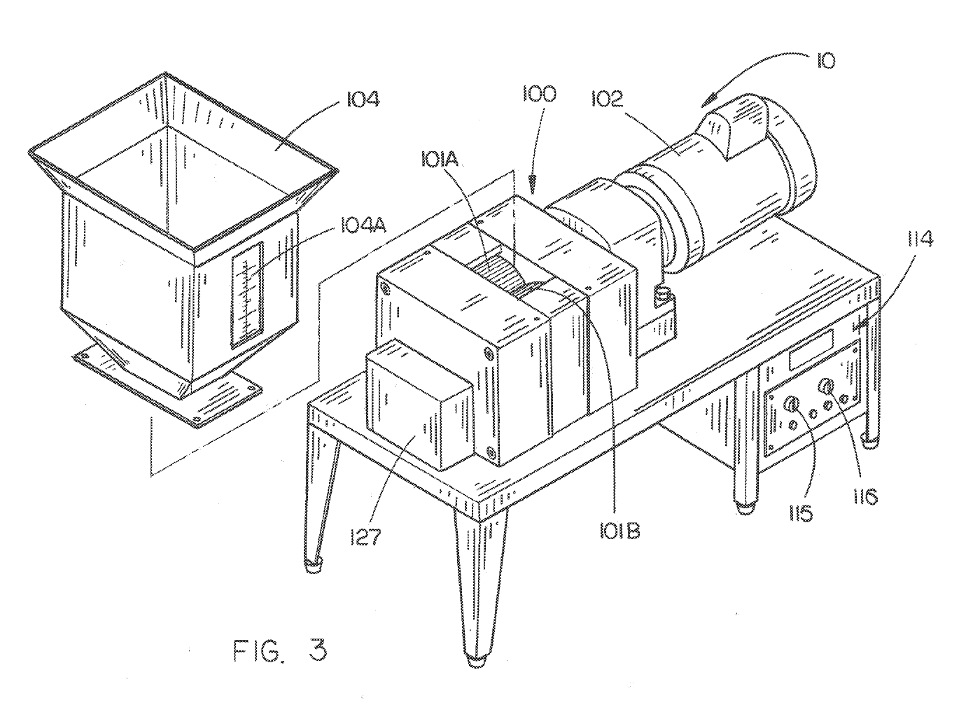

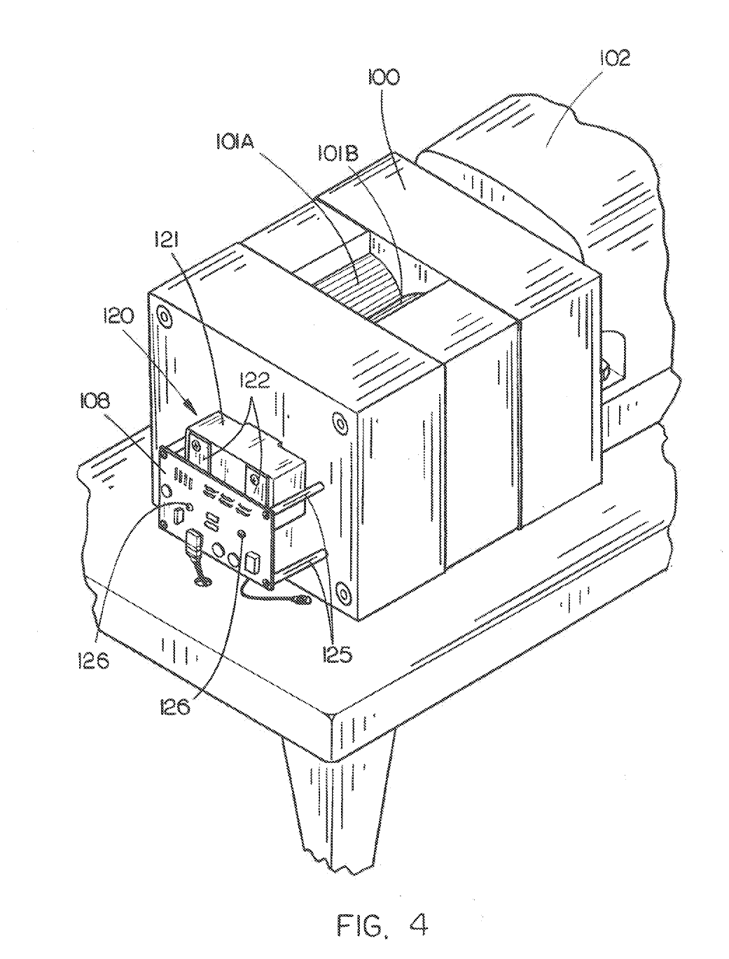

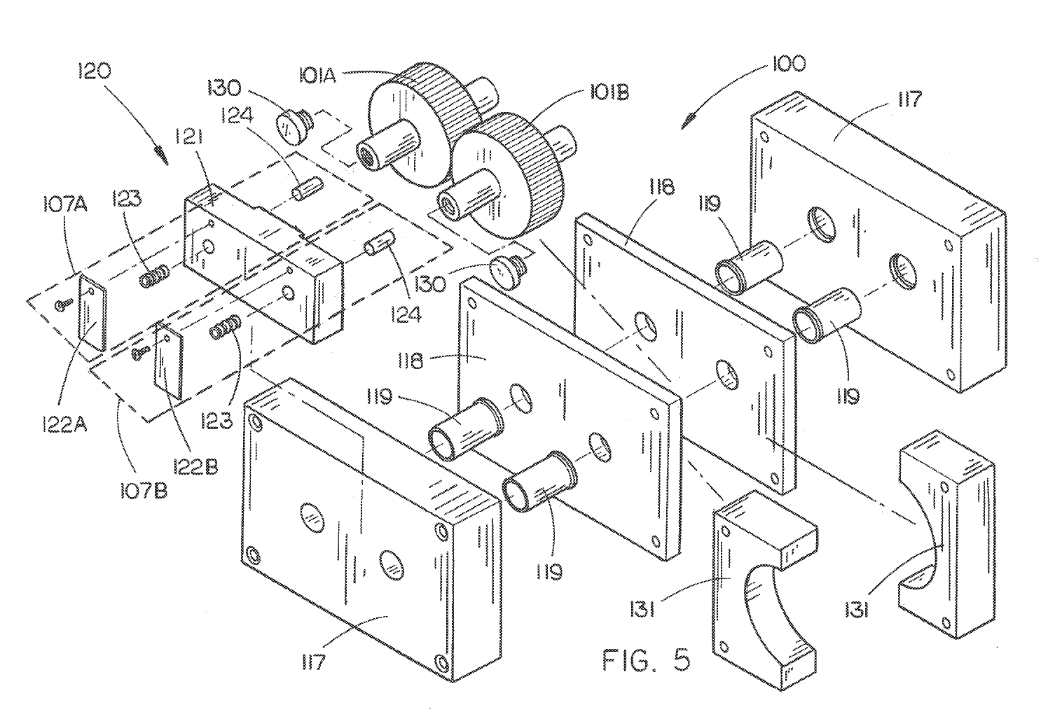

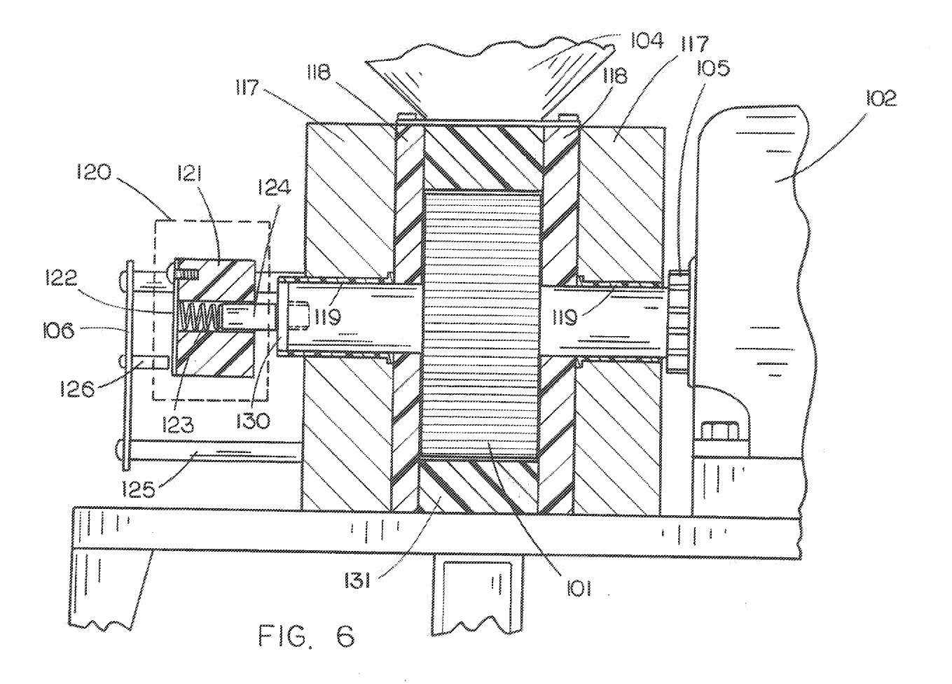

Referring to FIGS. 1-6, various depictions of the system 10 are shown. The system 10 may include a crush box 100 housing one or more crush rollers 101. A crush roller 101 (e.g. crush roller 101A) may be operably coupled to a motor 102 configured to drive the at least one of the crush rollers 101.

While depicted as cooperating roller-type configurations, it is fully contemplated that the crush rollers 101 may comprise any cooperating structures which are capable of drawing a quantity of conductive material between opposing conductive surfaces in an at least semi-continuous manner.

The motor 102 may be coupled to a crush roller 101 (e.g. crush roller 101A) via an electrically isolating coupler 103 (e.g. a torsional coupling such as those manufactured by Lovejoy, Inc.) The electrically isolating coupler 103 may provide electronic isolation of the crush rollers 101 from the motor 102 in order to maintain signal integrity of the detection circuitry 106, as will be discussed below. Particularly, no electronic interconnect (e.g. grounding circuitry) is made between the crush rollers 101 and the motor 102. The motor 102 may receive power from an external power source 110 (e.g. a standard 120 volt AC input).

The crush rollers 101 may be configured to rotate in order cooperatively to draw a quantity grain between the crush rollers 101. The crush rollers 101 may include knurled or milled surfaces to facilitate the introduction of grain between the crush rollers 101. The quantity of grain may be fed to the crush rollers 101 from a hopper 104. The hopper 104 may include a view window 104A including volumetric indicator markings enabling a user to visually monitor the amount of grain in the hopper 104.

In the case of a dual crush roller configuration, the crush rollers 101 may be configured to counter-rotate through use of cooperating drive gears 105. The drive gears 105 may be composed of electrically isolating materials (e.g. a first steel drive gear 105A and a second nylon drive gear 105B).

The system 10 may further include a detection module 127 housing detection circuitry 106 configured to detect the conductance through grain samples which pass between the crush rollers 101. The detection circuitry 106 may include a first interconnect 107A operably coupled to a first crush roller 101A and a second interconnect 107B coupled to the second crush roller 101B.

The first interconnect 107A and the second interconnect 107B may be coupled to an interface card 108. The interface card 108 may receive power from an external power source 110 (e.g. a standard 120 volt AC input) via an AC-to-DC converter 110A. In another example, the interface card 108 may receive power through a power-over-Ethernet or power-over-USB connection through a network adapter 111.

The interface card 108 may include the detection circuitry 106 as well as power handling circuitry 127. The power handling circuitry 127 may include power conditioning and buffering circuitry. For example, the power handling circuitry 127 may include surge suppression and diversion circuitry operably coupled to a ground circuit 129 in electronic isolation from the motor 102. The power handling circuitry 127 may further include and a unity gain buffer integrated circuit. This buffer may provide high current drive capability to an analog-to-digital converter (ADC 128) associated with the detection circuitry 106.

A DC electronic signal may be provided to the first crush roller 101A via the first interconnect 107A. When grain and/or an insect/insect larvae is disposed between the first crush roller 101A and the second crush roller 101B, the conductivity of the grain and/or insect/insect larvae may allow for the transmission of the signal between the first crush roller 101A and the second crush roller 101B. The signal may then be returned to the detection circuitry 106 via the second interconnect 107B.

In another example, the detection circuitry 106 may employ AC excitation detection (not shown) for measuring of the effective resistance element formed by the rollers, brushes, and crushed sample. The AC excitation signal may be rectified (e.g. by chopper stabilization) upstream of the ADC 128 to restore a DC equivalent signal which may be processed as discussed below.

The detection circuitry 106 may include a microprocessor 109 and the ADC 128.

The ADC 128 may be a 12-bit ADC chip which may convert an analog signal received via the second interconnect 107B into a digital value representing electrical conductivity.

The ADC 128 and its data stream may be managed by the microprocessor 109 which may read and/or format the information before storing it in an internal data queue 109A for delivery to a computing device 113.

The interface card 108 may further include a network adapter 111. The network adapter 111 may be configured to transceive input/output signals for the microprocessor 109 via a network medium 112 (e.g. Ethernet, USB, wireless network, etc.) to the computing device 113 (e.g. a application specific integrated circuit, a general purposed computing device (e.g. a laptop computer, a desktop computer), a smartphone, etc.) For example, network adapter 111 may include an RS232-to-USB bridge chip. The bridge chip may provides bidirectional communications with the computing device 113, allowing the computing device 113 to set or adjust various the parameters associated with the microprocessor 109 (e.g. sampling periods, sampling rates, reporting modes initiation and termination commands).

The interface card 108 may further comprise, computer readable instructions maintained in a computer readable memory component (e.g. firmware) which provides diagnostics, troubleshooting, and copyright verification functionality for the interface card 108. Further, the interface card 108 may include a signal test switch 132 configured to operably couple the first interconnect 107A and the interconnect 107B irrespective of the presence of a sample between the crush roller 101A and crush roller 101B. The signal test switch 132 may allow a user to perform various operations of the interface board and host communications without processing a sample or running the motor 102. A user may generate a full test run by collecting a dataset in this mode while simulating conductivity spikes by manual actuation of the signal test switch 132. This may allow for testing all elements of the electronics, firmware, host software, and configuration settings in a controlled manner and without consuming a grain sample.

The system 10 may further include a motor control module 114. The motor control module 114 may include one or more switches controlling the operation of the motor 102. For example, an operation switch 115 may be a tri-function switch configured to engage the motor 102 in an automatic, manual or off state. The automatic setting may cause the motor 102 to operate in a continuous manner. The manual setting may cause the motor 102 to operate only when a secondary switch is engaged (e.g. the operation switch 115 is moved into a fourth spring-resisted position). A directional switch 116 may be a tri-function switch configured to engage the motor 102 in a forward, off or momentary reverse manner.

The crush roller 101 may be disposed within one or more support portions 117 (e.g. aluminum support blocks). The support portions 117 may include one or more side plate portions 118 (e.g. Delrin plates) providing electronic isolation between the crush roller 101 and the support portions 117. Further, the support portions 117 may include one or more bearing mechanisms 119 (e.g. a plastic bearing sleeve) configured to minimize friction during rotation of the crush roller 101 within the support portions 117. The bearing mechanisms 119 may further serve to electrically isolate the crush roller 101 from the support portions 117.

The crush roller 101 may be disposed within one or more shield portions 131. The shield portions 131 may at least partially encircle the outside circumference of each crush roller 101. The clearance between the shield portions 131 and the crush rollers 101 may be such that the shield portions 131 may shear off conductive material that remains attached to a crush roller 101 following the material's initial pass through the crush rollers 101. Further, the shield portions 131 may be constructed of an insulating material (e.g. Delrin) so as to provide further galvanic isolation between the crushed conductive material sample and the aluminum crush frame.

The crush roller 101 may be operably coupled to the interface card 108 via an insulated brush block 120. The brush block 120 may include an insulated support portion 121 (e.g. a Delrin block) supporting at least one contact plate 122 (e.g. stainless steel contact plate 122A and 122B). The contact plate 122 may be electronically coupled to the crush roller 101 via a spring structure 123 (e.g. a coiled spring) supporting one or more conductive brushes 124 (e.g. carbon brushes).

The roller shaft of a crush roller 101 may terminate in conductive cap 130 (e.g. a brass cap). The cap 130 may be a screw-type cap including a threaded portion which may be received within a cooperating threaded aperture within the roller shaft of the crush roller 101. The cap 130 may be contacted by the conductive brushes 124 of the brush block 120.

The interface card 108 may be supported by one or more standoffs 125. The contact plate 122 may be electronically coupled to a circuit board contact 126 on the interface card 108.

Following are a series of flowcharts depicting exemplary implementations. For ease of understanding, the flowcharts are organized such that the initial flowcharts present implementations via an example implementation and thereafter the following flowcharts present alternate implementations and/or expansions of the initial flowchart(s) as either sub-component operations or additional component operations building on one or more earlier-presented flowcharts. Those having skill in the art will appreciate that the style of presentation utilized herein (e.g., beginning with a presentation of a flowchart(s) presenting an example implementation and thereafter providing additions to and/or further details in subsequent flowcharts) generally allows for a rapid and easy understanding of the various process implementations. In addition, those skilled in the art will further appreciate that the style of presentation used herein also lends itself well to modular and/or object-oriented program design paradigms.

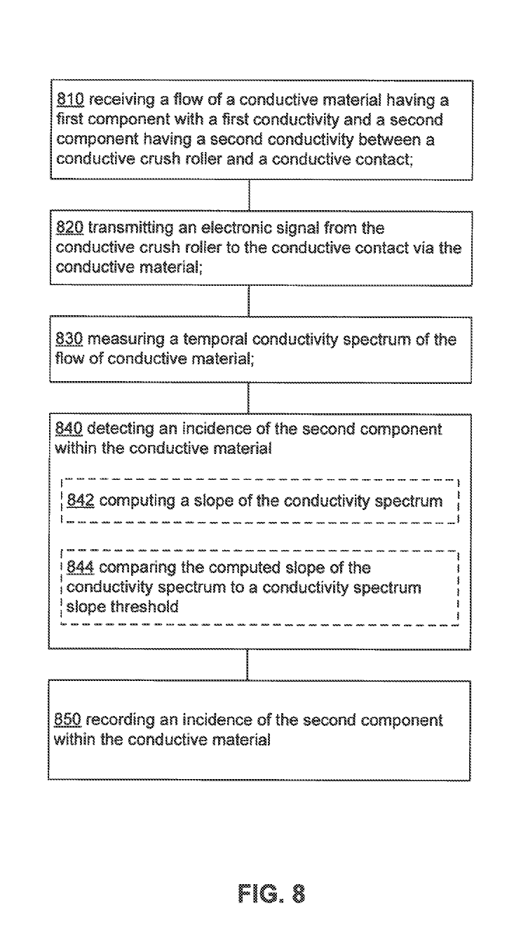

FIG. 8 illustrates an operational flow 800 representing example operations related to detection of insect/insect larvae present within a grain sample. In FIG. 8 and in following figures that include various examples of operational flows, discussion and explanation may be provided with respect to the above-described examples of FIGS. 1-6, and/or with respect to other examples and contexts. However, it should be understood that the operational flows may be executed in a number of other environments and contexts, and/or in modified versions of FIGS. 1-6. Also, although the various operational flows are presented in the sequence(s) illustrated, it should be understood that the various operations may be performed in other orders than those that are illustrated, or may be performed concurrently.

After a start operation, the operational flow 800 moves to an operation 810. Operation 810 depicts receiving a flow of a conductive material having a first component with a first conductivity and a second component having a second conductivity between a conductive crush roller and a conductive contact. For example, as shown in FIGS. 1-6, the motor 102 may drive at least one of the crush rollers 101 causing the crush rollers 101 to ingest a quantity of a conductive material (e.g. insect/insect larvae infested grain) including a first component having a first conductivity (e.g. the grain) and a second component having a second conductivity (e.g. the insect/insect larvae) from the hopper 104. The conductivity differences between the first component and the second component may be a result of the composition (e.g. the moisture content) of the first component and the second component.

Operation 820 depicts transmitting an electronic signal from the conductive crush roller to the second conductive contact via the conductive material. For example, as shown in FIGS. 1-6, when a conductive material (e.g. grain and/or insect/insect larvae) are disposed between the first crush roller 101A and the second crush roller 101B, the grain and/or insect/insect larvae provide a conductive path between the first crush roller 101A and the second crush roller 101B. The microprocessor 109 may output a signal via the first interconnect 107A to the first crush roller 101A. The signal may be transmitted through the conductive material to the second crush roller 101B and returned to the microprocessor 109 via the second interconnect 107B.

Operation 830 depicts measuring a temporal conductivity spectrum of the conductive material. For example, as shown in FIGS. 1-6, the microprocessor 109 may measure the signal strength (e.g. the voltage across the first crush roller 101A and the second crush roller 101B, the current passing between first crush roller 101A and the second crush roller 101B, etc.) associated with the conductive material entrained between the first crush roller 101A and the second crush roller 101B over a period of time. The signal strength may vary with the type of conductive material entrained at a given time (e.g. grain may have a lower conductivity as compared to an insect/insect larvae) thereby resulting in spectrum of output signal strengths on the second interconnect 107B during processing of a particular grain sample.

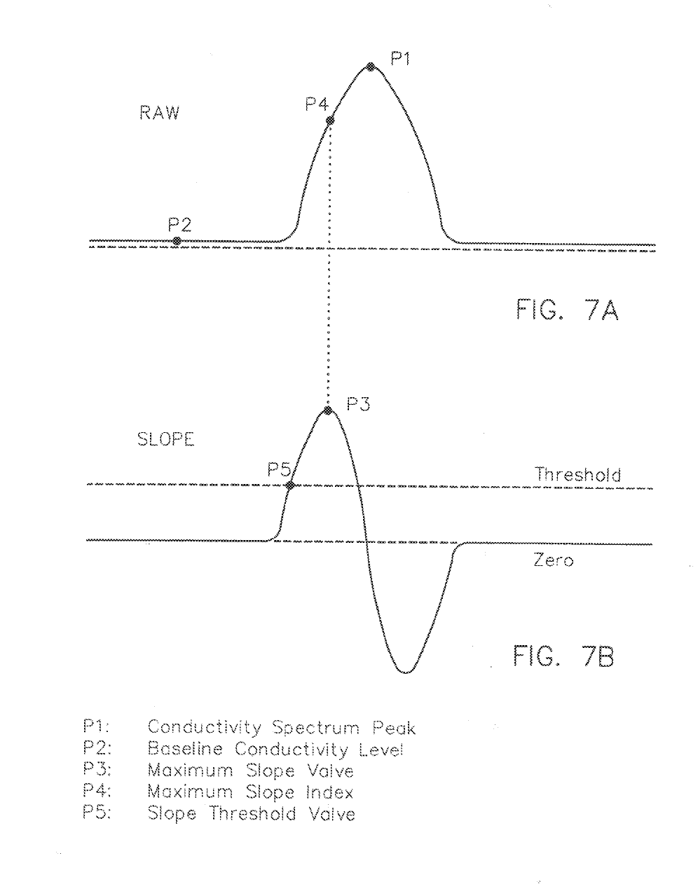

Operation 840 depicts detecting an incidence of the second component within the conductive material. For example, as shown in FIGS. 1-6, the microprocessor 109, may sample the signal returned via the second interconnect 107B and provide these data points to the computing device 113 as a output conductivity spectrum via the network adapter 111 and network medium 112. Referring to FIG. 7A, an exemplary illustration of the raw data comprising the conductivity spectrum is shown. The computing device 113 may process the conductivity spectrum to detect variations that may be associated with an incidence of the second component (e.g. the presence of insect/insect larvae) within a particular sample of the conductive material. A peak (e.g. P1) in the conductivity spectrum may indicate the presence of a second component having a greater relative conductivity (e.g. an insect/insect larvae) with respect to a baseline conductivity level (e.g. P2) associated with a first component (e.g. grain). The baseline conductivity level may by be inputted by a user desiring a particular level of sensitivity for the system or may be computed based on known characteristics of a conductive material component (e.g. the type of grain, the moisture content of a grain component, etc.)

Operation 840 may further include operations 542 and 544.

Operation 842 depicts computing a slope of the conductivity spectrum. The computing device 113 may compare various data points of the input conductivity spectrum of FIG. 7A to determine the relative differentials between those points. From those differentials, a slope of the conductivity spectrum at a given time index (e.g. P4) may be computed.

Operation 844 depicts comparing the computed slope of the conductivity spectrum to a conductivity spectrum slope threshold. Referring to FIG. 7B, an exemplary illustration of slope data corresponding to the raw conductivity spectrum data is shown. The computing device 113 may compare the value (e.g. P3) of a maximum slope (e.g. P4) of the raw data at the given time index to a predetermined slope threshold value (e.g. P5). The slope threshold by be inputted by a user desiring a particular level of sensitivity for the system or may be computed based on known characteristics of a conductive material component (e.g. the type of grain, the moisture content of a grain component, etc.)

Operation 850 depicts recording an incidence of the second component within the conductive material. If the slope data (e.g. P3) exceeds the slope threshold value (e.g. P4), the computing device 113 may detect this condition as an indication of an incidence of the second component (e.g. an insect/insect larvae) within the conductive material sample and store data reflecting such a detection in memory in the computing device 113. Following processing and recording, the second component incidence data may be displayed to a user via the computing device 113.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

What is claimed is:

1. A system comprising:
a first electrically conductive crush roller;
a second electrically conductive crush roller;
a drive motor operably coupled to at least one of the first electrically conductive crush roller and the second electrically conductive crush roller via an electrically isolating coupling;
detection circuitry configured to detect a signal transmitted from the first electrically conductive crush roller to the second electrically conductive crush roller when a conductive material is disposed between the first electrically conductive crush roller to the second electrically conductive crush roller.

2. The system of claim 1, further comprising:
one or more electrically isolating crush roller supports.

3. The system of claim 2, wherein the electrically isolating crush roller supports comprise:
an electrically insulating plate; and
an electrically insulating bearing sleeve.

4. The system of claim 1, wherein the detection circuitry further comprises:
an interface card including:
a microprocessor;
a first electrical interconnect operably coupled to the first electrically conductive crush roller; and
a second electrical interconnect operably coupled to the second electrically conductive crush roller.

5. The system of claim 4, wherein the detection circuitry further comprises:
a network adapter.

6. The system of claim 5, further comprising:
a computing device operably coupled to the network adapter.

7. The system of claim 6, wherein the computing device is configured for:
measuring a temporal conductivity spectrum of the conductive material;
determining a conductivity spectrum slope threshold associated with a conductivity of a first component of the conductive material;
detecting an incidence of a second component of the conductive material by:
computing a slope of the conductivity spectrum;
comparing the computed slope of the conductivity spectrum to a conductivity spectrum slope threshold; and
recording an incidence of the second component within the conductive material.

8. The system of claim 4, wherein at least one of the first electrical interconnect and the second electrical interconnect comprise:
a contact plate;
a spring operably coupled to the contact plate;
one or more brush elements operably coupled to the spring and configured to contact at least one of the first electrically conductive crush roller and the second electrically conductive crush roller.

9. The system of claim 1, wherein the conductive material comprises:
a grain component; and
at least one insect/insect larvae.

10. The system of claim 1, further comprising:
a signal test switch.

11. The system of claim 1, wherein at least one of the first electrically conductive crush roller and the second electrically conductive crush roller further comprise:
a conductive roller shaft cap.

12. The system of claim 1, further comprising:
power conditioning circuitry.

13. The system of claim 1, further comprising:
at least one crush roller shield at least partially encircling an outside circumference of at least one of the first electrically conductive crush roller and the second electrically conductive crush roller.

14. A method comprising:
receiving a flow of a conductive material having a first component with a first conductivity and a second component having a second conductivity between a conductive crush roller and a conductive contact;
transmitting an electronic signal from the conductive crush roller to the second conductive contact via the conductive material;
measuring a temporal conductivity spectrum of the conductive material;
detecting an incidence of the second component within the conductive material; and
recording an incidence of the second component within the conductive material.

15. The method of claim 14, wherein the detecting an incidence of the second component within the conductive material comprises:
computing a slope of the conductivity spectrum; and
comparing the computed slope of the conductivity spectrum to a conductivity spectrum slope threshold.

16. The method of claim 14, wherein the conductive contact is a second conductive roller.

17. The method of claim 14, wherein the receiving a flow of a conductive material having a first component with a first conductivity and a second component having a second conductivity between a conductive crush roller and a conductive contact comprises:
receiving a flow of a particulate conductive material having a first component with a first conductivity and a second component having a second conductivity between a conductive crush roller and a conductive contact.

18. The method of claim 17,
wherein the first component comprises a grain component; and
wherein the second component comprises at least one insect/insect larvae.

19. A system comprising:
means for receiving a flow of a conductive material having a first component with a first conductivity and a second component having a second conductivity between a conductive crush roller and a conductive contact;
means for transmitting an electronic signal from the conductive crush roller to the second conductive contact via the conductive material;
means for measuring a temporal conductivity spectrum of the conductive material;
means for detecting an incidence of the second component within the conductive material; and
means for recording an incidence of the second component within the conductive material.

20. The system of claim 19, wherein the means for detecting an incidence of the second component within the conductive material comprises:
means for computing a slope of the conductivity spectrum; and
means for comparing the computed slope of the conductivity spectrum to a conductivity spectrum slope threshold.

21. The system of claim 19, wherein the means for receiving a flow of a conductive material having a first component with a first conductivity and a second component having a second conductivity between a conductive crush roller and a conductive contact comprises:
means for receiving a flow of a particulate conductive material having a first component with a first conductivity and a second component having a second conductivity between a conductive crush roller and a conductive contact.
